(19) United States
(12) Patent Application Publication
(10) Pub. No.: US 2009/0224370 A1
(43) Pub. Date: Sep. 10, 2009

(54) NON-PLANAR CVD DIAMOND-COATED CMP PAD CONDITIONER AND METHOD FOR MANUFACTURING

(76) Inventor: David E. Slutz, Bethlehem, PA (US)

Correspondence Address: JOHN S. PRATT, ESQ;KILPATRICK STOCKTON, LLP, 1100 PEACHTREE STREET, SUITE 2800, ATLANTA, GA, 30309, US

(21) Appl. No.: 12/399,267

(22) Filed: Mar. 6, 2009

Related U.S. Application Data
(60) Provisional application No. 61/035,200, filed on Mar. 10, 2008.

(51) Int. Cl. H01L 29/30; B24B 53/02; H01L 21/306; B24D 3/00

(52) U.S. Cl. 257/618; 451/56; 438/692; 51/308; 51/309; 257/E29.106; 257/E21.23

(57) ABSTRACT

The present invention relates to a composite material having non-planar geometries and edge-shaving surfaces comprising a CVD diamond coating applied to a composite substrate made from a ceramic material and a preferably unreacted carbide-forming material of various configurations and for a variety of applications.

### CROSS REFERENCE

This application claims priority from U.S. Provisional Patent Application Ser. No. 61/035,200 filed Mar. 10, 2008, the contents of which are herein incorporated by reference as if made a part of this present specification.

### FIELD OF THE INVENTION

The present invention relates generally to a product comprising a layer of CVD diamond coating applied to a composite substrate of ceramic material and a carbide-forming material of various configurations and for a variety of applications, and methods for manufacturing these products. More specifically, the present invention relates to products comprising at least one layer of CVD diamond coating applied to a composite substrate of ceramic material and a carbide-forming material of various non-planar configurations and for a variety of applications, and methods for manufacturing these products.

### BACKGROUND OF THE INVENTION

The products of the present invention have utility in a wide variety of applications, including heads or disks for the conditioning of polishing pads, including pads used in Chemical-Mechanical-Planarization (CMP). CMP is an important process in the fabrication of integrated circuits, disk drive heads, nano-fabricated components, and the like. For example, in patterning semiconductor wafers, advanced small dimension patterning techniques require an absolutely flat surface. After the wafer has been sawed from a crystal ingot, and irregularities and saw damage has been removed by rough polishing, CMP is used as a final polishing step to remove high points on the wafer surface and provide an absolutely flat surface. During the CMP process, the wafer will be mounted in a rotating holder or chuck, and lowered onto a pad surface rotating in the same direction. When a slurry abrasive process is used, the pad is generally a cast and sliced polyurethane material, or a urethane-coated felt. A slurry of abrasive particles suspended in a mild etchant is placed on the polishing pad. The process removes material from high points, both by mechanical abrasion and by chemical conversion of material to, e.g., an oxide, which is then removed by mechanical abrasion. The result is an extremely flat surface.

In addition, CMP can be used later in the processing of semiconductor wafers, when deposition of additional layers has resulted in an uneven surface. CMP is desirable in that it provides global planarization across the entire wafer, is applicable to all materials on the wafer surface, can be used with multi-material surfaces, and avoids use of hazardous gases. As an example, CMP can be used to remove metal overfill in damascene inlay processes.

CMP represents a major portion of the production cost for semiconductor wafers. These CMP costs include those associated with polishing pads, polishing slurries, pad conditioning disks and a variety of CMP parts that become worn during the planarizing and polishing operations. The total cost for the polishing pad, the downtime to replace the pad and the cost of the test wafers to recalibrate the pad for a single wafer polishing run can be quite high. In many complex integrated circuit devices, up to five CMP runs are required for each finished wafer, which further increases the total manufacturing costs for such wafers.

With polishing pads designed for use with abrasive slurries, the greatest amount of wear on the polishing pads is the result of polishing pad conditioning that is necessary to place the pad into a suitable condition for these wafer planarization and polishing operations. A typical polishing pad comprises closed-cell polyurethane foam approximately 1/16 inch thick. During pad conditioning, the pads are subjected to mechanical abrasion to physically cut through the cellular layers of the surface of the pad. The exposed surface of the pad contains open cells, which trap abrasive slurry consisting of the spent polishing slurry and material removed from the wafer. In each subsequent pad-conditioning step, the ideal conditioning head removes only the outer layer of cells containing the embedded materials without removing any of the layers below the outer layer. Such an ideal conditioning head would achieve a 100 % removal rate with the lowest possible removal of layers on the polishing pad, i.e., lowest possible pad wear rate. It is apparent that a 100 % removal rate can be achieved if there were no concern for the adverse affect on wear of the pad. However, such over-texturing of the pad results in a shortening of the pad life. On the other hand, under-texturing results in insufficient material removal rate during the CMP step and lack of wafer uniformity. Using the conventional conditioning heads that achieve satisfactory removal rates, numbers of wafer polishing runs as few as 200 to 300 and as many as several thousand (depending on the specific run conditions) can be made before the pad becomes ineffective and must be replaced. Replacement typically occurs after the pad is reduced approximately to half of its original thickness.

As a result, there is a great need for a conditioning head that achieves close to an ideal balance between high wafer removal rates and low pad wear rate so that the effective life of the polishing pad can be significantly increased without sacrificing the quality of the conditioning.

One alternative to the urethane polishing pads described above is a woven or non-woven fiber CMP pad, which may incorporate polyurethane. Like the polyurethane pads, the woven pads are designed for use with an abrasive slurry, but provide an alternative to polyurethane CMP pads that gives finer polishing. While the weave of these pads is quite dense, there is opportunity for slurry particles to become trapped within the weave. These particles must be removed from the weave during conditioning. Efficiency of removal of used slurry components must be balanced against damage to the fibers of the weave caused by contact with the conditioning head surface, which can cause excessive breakage of the fibers.

Another alternative is a pad that is a solid pad comprising substantially uniformly dispersed water-soluble particles (WSP), having a configuration and design based upon proprietary elastomer technologies, and well-established polymer alloying methods. During conditioning and polishing, the WSP is exposed to the aqueous slurry. The WSP on the pad surface dissolves, leaving behind pores. This results in a porous surface with a hard “under” pad. A similar pad concept comprises a pad comprising a thermoplastic-containing material. During the polishing process, heat is generated, which, in turn, heats the surface of the pad. This heat softens the surface of the pad, resulting in a harder pad with a softer surface.

An alternative to CMP polishing pads designed for use with an abrasive slurry, known as a “fixed abrasive” polishing pad, has been developed in order to avoid the disadvantages associated with using a separate slurry composition. One example of such a polishing pad is the 3M Slurry-Free CMP Pad #M3100. This pad contains a polymer base upon which has been deposited 0.2-micron cerium oxide abrasive in approximately 40 micron tall×200 micron diameter pedestals. These pads also require conditioning, because the CMP polishing rate obtained when using the pads is highly sensitive to the surface properties of the abrasive. Initial “breaking in” periods for these polishing pads, during which consistent quality polishing is difficult to obtain, tend to be long, and the resulting loss of wafers is an added expense. Proper conditioning of these pads can reduce or eliminate this break-in period, and reduce or avoid the loss of production wafers.

Typical diamond-containing conditioning heads have a metal substrate, e.g., a stainless steel plate, with a non-uniform distribution of diamond grit over the surface of the plate and a wet chemical plated over-coat of nickel to cover the plate and the grit. The use of such conventional conditioning heads is limited to the conditioning of polishing pads that have been used during oxide CMP wafer processing, i.e. when the exposed outer layer of the polishing pad is an oxide-containing material as opposed to metal. In processing a semiconductor wafer, there are about the same number of oxide and metal CMP processing steps. However, the conditioning heads described above are ineffective for conditioning polishing pads used in metal CMP processing, because the slurry used to remove metal from the wafer can react with the nickel and degrade and otherwise dissolve the nickel outer layer of the conditioning head. Dissolution of the nickel overcoat can result in a major loss of the diamond grit from the plate, potentially scratching the wafers.

An alternative conditioner head is made by brazing or sintering the diamond crystals to a metal substrate, the brazing or sintering improves the adhesion of the diamond crystals to the metal substrate by forming chemical bonds. Conditioners of this type can be made with substantially uniformly placed diamond crystals on the surface, or randomly placing such diamonds. In certain instances, the conditioner is then coated with a chemically inert material to protect the conditioner from acidic metal slurries.

In addition, these typical conditioning heads use relatively large sized diamond grit particles. Similar large particles are disclosed in Zimmer et al. (U.S. Pat. Nos. 5,921,856 and 6,054,183, the entire contents of which are incorporated by reference herein as if made a part of the specification). Instead of using a nickel overcoat, Zimmer et al. bond the diamond grit to the substrate with a chemical vapor deposited polycrystalline diamond film (“CVD diamond”). The diamond grit, commercially available from the cutting of natural diamonds and from industrial grade diamonds using high-pressure processes, is incorporated into the structure of the thin CVD diamond film. The size of the grit is chosen so that the peak-to-valley surface distance is greater than the thickness of the CVD diamond film. The diamond grit is uniformly distributed over the surface of the substrate at a density such that the individual grains are separated by no less than ½ the average grain diameter. The average size of the diamond grit is in the range of about 15 microns to about 150 microns, preferably in the range of about 35 microns to about 75 microns. By controlling the size and surface density of the diamond grit, the abrasive characteristics of the resulting surface can be adjusted for various conditioning applications. The grain sizes on a given disk will be relatively consistent in size, to approximately ±20%.

Roughness of a surface can be measured in a number of different ways, including peak-to-valley roughness, average roughness, and RMS roughness. Peak-to-valley roughness (Rt) is a measure of the difference in height between the highest point and lowest point of a surface. Average roughness (Ra) is a measure of the relative degree of coarse, ragged, pointed, or bristle-like projections on a surface, and is defined as the average of the absolute values of the differences between the peaks and their mean line. RMS roughness (Rq) is a root mean square average of the distances between the peaks and valleys. “Rp” is the height of the highest peak above the centerline in the sample length. “Rpm” is the mean of all of the Rp values over all of the sample lengths. Rpm is the most meaningful measure of roughness for gritless CMP pads, since it provides an average of the peaks that are doing the bulk of the work during conditioning. However, a new generation of CMP pads, including fixed abrasive pads and many woven pads, cannot be conditioned by conventional conditioners because conditioning heads having grit particles larger than 15 microns are too rough; the large grit particles tend to damage the pad.

An alternative to using diamond grit is disclosed in U.S. Ser. No. 10/091,105, filed Mar. 4, 2002, the entire contents of which are incorporated by reference herein, as if made a part of the present specification. This application describes the use of CVD diamond coating on a polished silicon substrate, preferably without the use of diamond grit, to create the abrasive surface and to control the conditioning rate. The surface roughness resulting from simply growing CVD diamond on a silicon substrate ranges from about 6 to microns from peak-to-valley on a substrate having a thickness of 25 microns of CVD diamond. In general, the surface roughness for a typical operation ranges from about ¼ to about ½ the thickness of the CVD diamond that is grown on the substrate. This degree of surface roughness can provide the desired abrasive efficiency for CMP conditioning operations for fixed abrasive CMP pads. However, difficulties with this approach are the lack of independent control of the particle size and density of working diamond grains, and the resulting bow of the diamond-coated silicon substrate product.

While silicon has been used successfully as a substrate for CVD diamond in preparation of some CMP pad conditioners, in accordance with one embodiment of this invention of this application, it has been found that a silicon substrate does not provide sufficient rigidity to support diamond coatings of sufficient thickness to provide optimal CMP conditioning in some applications with sensitive pad materials. Because of both internal growth stress in CVD diamond materials, and the mismatch in thermal coefficients of expansion between diamond and silicon, a CVD diamond-coated silicon substrate conditioning head will bow or bend, even when supported by a metal backing plate, resulting in a conditioner that is not completely flat. A bowed conditioning head does not provide as consistent conditioning as a flat conditioning head, and is thus less desirable.

An alternative to using silicon substrate is disclosed in commonly owned and co-pending, and commonly assigned US Publication No. US2005/0276979, filed Jun. 24, 2005, which is incorporated by reference in its entirety, as if made a part of the present specification. This application discloses the use of a flat substrate, preferably ceramic, consisting of a carbide and carbide-forming phase, with or without diamond grit, to create an abrasive surface, and to control the conditioning rate. This disclosure teaches that conditioners can be made that will have the degree of substrate bow substantially unchanged after CVD diamond deposition. This reference teaches, that producing conditioners with substantially no “bow” introduced during diamond deposition maximizes the surface area in contact with the CMP pad during polishing. The high contact area is thought to provide a more uniform conditioning, and longer pad life.

In spite of recent advances, there remains a need in the art for polishing pad conditioners that can condition the surface of a pad without creating large asperities. Asperities are defined in the industry as protrusions of pad material beyond the mean pad surface. The conditioning of a pad with conditioners fabricated using diamond grit particles, produces a textured pad surface due to each diamond grain “point cutting” an impact site, by scratching or otherwise forming a “groove” in the pad surface. These grooves then overlap, or “criss-cross” or randomly overlap over the surface of the pad, forming varying textures in the pad surface from center to edge. Large asperities in the pad can cause defects on the wafer surface during CMP operations, especially for the latest technology where wafer features are much finer than previous technologies. These finer features are more fragile and susceptible to damage from large asperities on the pad surface. Therefore, there is a need for conditioners that can condition the pad surface without forming these large asperities, and which can retain the diamond cutting surfaces securely.

### SUMMARY OF THE INVENTION

Embodiments of the present invention overcome these prior art problems in the fabrication of CMP pad conditioners via the use of a composite ceramic non-planar substrate for the deposition of CVD diamond. In addition, embodiments of the present invention overcome shortcomings in conventional materials and processes by providing a CVD diamond-coated ceramic material composite product that has advantages of superior adhesion of the CVD diamond material, and is a strong, resilient and tough composite material that is resistant to fracture at a low cost compared to conventional CVD diamond component products.

According to further embodiments, the present invention is directed to polishing pad conditioning heads having a composite ceramic substrate and a CVD diamond coating deposited thereon, wherein the conditioning heads comprise desirable non-planar surfaces and surface features. More specifically, the preferred conditioning heads, according to embodiments of the present invention, comprise predictable, edge-shaving raised surfaces and surface features that assist in the desired usefulness of the conditioning head. Further, without being bound to one particular theory, it is believed that, in most circumstances, the non-planar surface features of the conditioning heads obviate the need for additional diamond grit deposition. The non-planar edge-shaving features are preferably linear or non-linear line segments oriented into preferred or random arrangements including, for example, concentric circles, broken line, or staggered concentric circles, spirals, broken line spirals, rectangles, broken line rectangles, irregular patterns, etc. While many possible raised and oriented arrangements are possible, broken-line or continuous concentric circles and spirals, and concentric circle and spiral segments are particularly preferred. The term “non-planar” refers to the existence of edge-based shaving or shaping features raised out of the natural plane of the otherwise substantially level conditioning head. In this way, the edge-shaving raised features are said to be out of plane, or non-planar relative to the conditioning head plane.

Embodiments of the present invention are broadly directed to a composite article comprising a substrate having a surface, with the substrate comprising a first phase comprising at least one ceramic material, wherein the surface comprises pre-determined patterns raised out of the natural plane of the substrate surface.

Further embodiments of the present invention are directed to a composite article comprising a substrate having a surface, with the substrate comprising a first phase comprising at least one ceramic material, and a second phase comprising at least one material having a higher adhesion to chemical vapor deposited diamond than the ceramic material. A chemical vapor deposited diamond coating is then disposed on at least a portion of a surface of the substrate, the substrate surface being is non-planar. That is, the substrate surface comprises at least one area of raised orientation out of the natural plane of the substrate surface, the surface area of the raised orientation comprising an edge-shaving or shaping surface.

Still further embodiments of the present invention relate to a composite article comprising a substrate having a surface, with the substrate comprising a first phase comprising at least one ceramic material, and a second phase comprising at least one material having a higher adhesion to chemical vapor deposited diamond than the ceramic material. A chemical vapor deposited diamond coating is then disposed on at least a portion of a surface of the substrate, the substrate surface being is non-planar. That is, the substrate surface comprises at least one area or region of raised orientation out of the natural plane of the substrate surface, and the conditioning head is resistant to bowing.

By “resistant to bowing”, it is understood that the uncoated substrate has a first planarity, and that the deposited diamond coating creates a coated substrate that has a second planarity that is substantially similar to the first planarity.

At least one of the second phase materials is desirably a carbide-forming material, and may be dispersed in a matrix formed by the first phase ceramic material. The regions of carbide-forming material within the composite structure preferably may comprise a coating on one or more pores formed within the regions of the first phase of ceramic material. The regions of carbide-forming material preferably may be formed within the composite structure by infiltration of the carbide-forming material within one or more pores formed within the regions of the first phase ceramic material.

Preferably the ceramic phase comprises between 30 volume % and 99 volume % of the substrate, more preferably between 50 volume % and 95 volume % of the substrate. The carbide-forming phase having a higher adhesion to chemical vapor deposited diamond than the ceramic phase preferably comprises between 1 volume % and 70 volume % of the substrate, more preferably between 5 volume and 50 volume % of the substrate.

Alternatively, at least one of the first phase ceramic materials may be dispersed in a matrix formed by the second phase carbide-forming material. In this case, the first ceramic phase may comprise one or more grains of the ceramic material dispersed within a matrix of the second phase comprising the carbide-forming material.

In particular, the invention advantageously provides a CVD diamond coated composite substrate where the substrate comprises phases of an unreacted carbide-forming material and ceramic material. The CVD diamond coating thickness is preferably between from about 0.1 micron to about 2 mm depending on the application, more preferably from about 1 to about 25 microns, and most preferably from about 10 to about 18 microns. According to one embodiment, the present invention relates to the discovery that composites of a ceramic material and an unreacted phase of a carbide-forming material provide an excellent and superior substrate for deposition and growth of CVD diamond coatings, resulting in materials having thinner and more securely adhered diamond coatings that can be used in applications such as CMP polishing pad conditioners, cutting tools, wear components, and heat distribution elements such as heat spreaders for use in, e.g., electronics packages.

As used herein, the term “ceramic” is to be interpreted in its widest sense as including not only oxides but also non-oxide materials, for example, such as, silicon carbide or silicon nitride, etc. The ceramic material phases of the composite substrate of the present invention provide the stiffness required to maintain the diamond-coated composite product “flat”, or substantially planar; the presence of the second phase material (the carbide-forming material) provides strength and toughness, resulting in a very strong, tough, and adherent composite diamond-coated product, which has an overall planarity that is substantially similar to the uncoated substrate planarity. As used herein, the term “carbide-forming material” means a material that is capable, under appropriate conditions, of formation of a covalently bonded compound with carbon in a carbide. While not being bound to any particular theory, it is believed that regions of the carbide-forming material react with the depositing CVD diamond material to form regions of bonded carbide structures at the interface between the substrate and the CVD diamond layer, resulting in strong and superior adhesion of the diamond layer to the substrate as compared to known structures.

In a more particular embodiment, the ceramic phase is composed of silicon carbide and the unreacted phase of carbide-forming material is silicon metal. This material, known as Reaction-Bonded Silicon Carbide (“RBSiC”), has considerably better fracture toughness than does pure silicon, and provides much better dimensional stability, resulting in a flatter CVD diamond-coated composite product, such as a polishing pad conditioner. In particular, reaction-bonded silicon carbide or graphite-silicon carbide composites having dispersed therein a dispersed phase of silicon metal, or having grains of silicon carbide dispersed within a silicon metal matrix, are particularly suitable substrates for CVD diamond coatings of the present invention.

In one embodiment, the invention relates to a composite material comprising a surface and having a first phase comprising silicon carbide, a second phase comprising silicon metal, and a layer of chemical vapor deposited diamond adhering to at least a portion of the surface. The invention also relates to a polishing pad conditioning head comprising a substrate having a surface and comprising a first phase comprising silicon carbide, a second phase comprising silicon metal, optional diamond grit particles, and a polycrystalline diamond coating disposed on at least a portion of the substrate. In a particular embodiment, this polishing pad conditioner does not contain an adhesive layer disposed between the silicon carbide surface and the polycrystalline diamond surface. Put another way, in this particular embodiment, at least a portion of the silicon carbide in the substrate is in direct contact with the polycrystalline diamond layer.

In addition, the invention relates to the discovery that damage to fixed abrasive pads (and other sensitive CMP pads) resulting from contact with conditioning heads can be considerably reduced by avoiding the presence of large diamond crystals in the conditioning head surface due to the “point cutting” aspect of the larger individual diamond crystals ordinarily grown. Large crystals have been found to provide a disproportionate share of conditioning, but also to cause a disproportionate share of damage to the CMP polishing pad. A reduced level of such crystals was found to be obtainable through the preparation of conditioning heads surfaces that are significantly more homogeneous than previously available on previously described surfaces. However, this reduced number of large crystals and improved homogeneity of the surface results in the necessity to increase the down force applied to the conditioner in order to obtain the desired level of conditioning using commercially available CMP polishing equipment. Increased homogeneity can be achieved by carefully controlling the particle size distribution of any diamond grit applied to the surface, carefully controlling the density of grit particles per unit area of the coated substrate, or growing a CVD diamond layer on pre-roughened substrates, so that the roughness of the diamond layer is in part determined by the surface roughness of the substrate.

In another embodiment, the invention is directed to a polishing pad conditioning head which has a substrate, a layer of diamond grit having an average grain size ranging from about 1 to about 15 microns, substantially uniformly distributed on the substrate, and an outer layer CVD diamond grown onto the resulting grit covered substrate to at least partially encase and bond said polycrystalline diamond grit to said surface. In a particular embodiment, the resulting conditioning head contains a grit-covered substrate encased in polycrystalline CVD diamond having a thickness of at least about 20% of the grit size, resulting in a total diamond coating thickness preferably of from about 1 to about 18 microns. In another embodiment, the conditioning head also contains diamond grit having an average diameter of less than 1 micron. This smaller grit is substantially uniformly distributed over the substrate and first layer of grit.

In another embodiment, the conditioning head contains a substrate that has been coated with a first layer of CVD polycrystalline diamond prior to distributing the layer or layers of diamond grit, and the grit coated surface is then coated with a second layer of CVD polycrystalline diamond. In this embodiment, the diamond grit may include the layer of 1-micron to 15-micron diamond grit described above, or may also include the less than 1-micron diamond grit, also described above.

Any of the above-described embodiments may contain a substrate that has been coated on one or both sides thereof, and the coatings may be the same or different, so long as at least one coating falls within the scope of one of the embodiments described above.

In another embodiment, the invention relates to methods for making the polishing pad conditioning heads described above. One preferred embodiment of the method involves first uniformly distributing a first layer of diamond grit having an average particle diameter in the range of from about 1 to about 15 microns over an exposed surface of a substrate to achieve an average grit density in the range from about 100 to about 50000 grains per mm². A chemical vapor layer of polycrystalline diamond is then deposited onto the exposed surface of the grit covered substrate to render a polishing pad conditioning head product having a grit covered substrate encased in polycrystalline diamond having a thickness of at least about 20% of the grit size.

Similarly, when a layer of polycrystalline diamond is to be deposited prior to distribution of the diamond grit, the method preferably involves chemical vapor depositing a layer of polycrystalline diamond onto an exposed surface of a substrate and then uniformly distributing a first layer of diamond grit over an exposed surface of said layer of polycrystalline diamond to achieve an average grit density in the range from about 100 to about 50000 grains per mm². An outer layer of polycrystalline diamond is then chemical vapor deposited onto the exposed surface of the grit covered substrate, rendering a polishing pad conditioning head product having a grit covered substrate encased in polycrystalline diamond having a thickness of at least about 20% of the grit size. In this preferred embodiment of the invention, the diamond grit may range widely in size, from as small as submicron grit to greater than 100 microns. In a particular embodiment, the average diameter of the diamond grit is in the range of from about 1 to about 15 microns.

When diamond grit is desired on two sides of the substrate, according to an embodiment of the present invention, the method for making the conditioning head includes substantially uniformly distributing a layer of diamond grit having an average particle diameter in the range of from about 1 to about 150 microns over an exposed surface of a first side of a substrate to achieve an average grit density in the range from about 100 to about 50000 grains per mm², followed by chemical vapor depositing an outer layer of polycrystalline diamond onto the exposed surface of the grit covered side. The substrate is then cooled, and a layer of diamond grit having an average particle diameter in the range of from about 1 to about 150 microns is substantially uniformly distributed over an exposed surface of a second side of said substrate to achieve an average grit density in the range from about 100 to about 50000 grains per mm². This process is preferably repeated, rendering a polishing pad conditioning head product having both sides of said substrate covered with grit and encased in polycrystalline diamond having a thickness of at least about 20% of the grit size for each side.

In another embodiment, the present invention relates to a polishing pad conditioning head having substrate material comprising a first phase of a ceramic material and a second phase of a carbide-forming material, described above, further comprising a first layer of diamond grit having an average grain size in the range of about 15 microns to about 150 microns and substantially uniformly distributed with respect to an exposed surface of the substrate. The layer of chemical vapor deposited diamond is preferably disposed on the diamond grit-covered substrate, with the layer of chemical vapor deposited diamond at least partially encasing and/or bonding the diamond grit to the substrate. More particularly, the diamond grit can range from about 15 microns to about 75 microns.

In another embodiment, the present invention relates to polishing pad conditioning heads having a substrate, and a CVD diamond coating deposited thereon, wherein the surface of the coating has an average roughness (Ra) of at least about 0.30 microns, more particularly, at least about 0.40 microns. It is believed that this degree of surface roughness can provide enhanced conditioning results on non-fixed abrasive pads, as compared to conditioning heads with lower roughness levels.

The conditioning head of the invention is suitable for the conditioning of polishing pads that require very gentle conditioning. The conditioning head for a CMP and similar types of apparatuses has been found to condition the pads with significantly reduced damage to the structure of the pad, as compared to the potential surface damage caused by conventional conditioning heads. This in turn has shown to extend the life of the polishing pad without sacrificing wafer removal rates and methods for making the polishing pads. Among other advantages, the conditioning head of the present invention:

(1) is effective in conditioning polishing pads used to process metal as well as oxide surfaces;

(2) is manufactured so that the diamond coating is more firmly attached to the substrate and consequently does not detach from the substrate to potentially scratch the wafer; and

(3) provides a greater degree of uniformity of material removed across a given wafer.

The conditioning heads of the present invention can be used to condition either fixed abrasive pads or pads for use with abrasive slurries. This invention is capable of conditioning polishing pads used to planarize and/or polish surfaces, such as, for example, dielectric and semiconductor (oxide) films and metal films on semiconductor wafers as well as to planarize and/or polish wafers and disks used in computer hard disk drives, etc.

According to still another embodiment, the present invention relates to a method of substantially uniformly depositing diamond grit on a substrate, comprising suspending particles of diamond grit in an alcohol, applying the suspension to a substrate surface having a net positive charge, and removing excess diamond particles from the surface before evaporating the alcohol.

In yet another embodiment, the present invention contemplates to a method for making the composite substrate material coated according to the embodiments described above, where a porous ceramic body is formed from particles of ceramic materials such as silicon carbide, silicon nitride, silicon aluminum oxynitride, aluminum nitride, tungsten carbide, tantalum carbide, titanium carbide, boron nitride, and similar materials, etc. and combinations thereof. The ceramic material may desirably be silicon carbide. The porous ceramic body is infiltrated with a carbide-forming material, such as silicon, titanium, molybdenum, tungsten, niobium, vanadium, hafnium, chromium, zirconium, and other materials, including mixtures of these, with silicon being particularly suitable. In all cases, the choice of ceramic and carbide-forming materials is chosen from materials that are stable in the environment used to deposit diamond via chemical vapor deposition, i.e. stable in an atmosphere containing hydrocarbon and a large concentration of hydrogen at temperatures in the range of from about 600° C. to about 1100° C. It is particularly preferred that the carbide forming phase comprising a carbide-forming material has a higher adhesion to chemical vapor deposited diamond that the ceramic phase.

In still another embodiment, the invention relates to relates to polishing pad conditioning heads having a substrate, and a CVD diamond coating deposited thereon, wherein the conditioning heads comprise desirable non-planar surface features. More specifically, the conditioning heads of the present invention comprise predictable or unpredictable, raised surface features that assist in the desired usefulness of the conditioning head. According to preferred embodiments, it is believed that, in most circumstances, the non-planar surface features of the conditioning heads, obviate the need for additional deposition of diamond grit. The non-planar edge-shaving or shaping features or regions are preferably linear or non-linear line segments oriented into arrangements including, for example, concentric circles, broken line, or staggered concentric circles, spirals, broken line spirals, rectangles, broken line rectangles, etc. While many possible raised and oriented arrangements are possible, concentric circles and spirals are particularly preferred. The term “non-planar” refers to the existence of features raised out of the natural plane of the otherwise substantially planar conditioning head. In this way, the raised edge-shaving features or regions are said to be out of plane, or non-planar relative to the conditioning head plane. According to embodiments of the present invention it is further preferred that the raised features have a substantially uniform height out of the plane of the substrate surface, however, it is understood that the height of the raised surface may be tailored to achieve a desired result, such that the raised features (according to the desired result) may or may not be of substantially consistent dimension relative to height, length and width.

As mentioned above, embodiments of the present invention relate to polishing and conditioning heads where the head substrate surface features obviate the detrimental effects presented by conventional heads using “point cutting” methodologies. Instead, embodiments of the present invention provide pre-selected non-planar, raised surface features that effect an improved pad conditioning surface due to the presence of “edge based shaping” methodologies.

Further objects, advantages and embodiments of the invention will become evident from the reading of the following detailed description of the invention wherein reference is made to the accompanying drawings

### BRIEF DESCRIPTION OF DRAWINGS

FIG. 1 illustrates a 2″ AND 4″ CMP pad conditioner made in accordance with embodiments of US Publication No. US2005/0276979, filed Jun. 24, 2005;

FIG. 2 illustrates a 4″ CMP pad conditioner made in accordance with embodiments of US Publication No. US2005/0276979, filed Jun. 24, 2005. This conditioner is mounted into a PP backing fixture instead of a stainless steel fixture

FIG. 3 illustrates the surface of a CMP pad conditioner made in accordance with embodiment of US Publication No. US2005/0276979, filed Jun. 24, 2005. The illustrations shows the single crystal diamond bonded to the ceramic serrate via CVD diamond coating

FIG. 4 is a photograph showing the surface of a CMP Pad Conditioner made in accordance with embodiments of US Publication No. US2005/0276979, filed Jun. 24, 2005.

FIG. 5 is a representation of the surface of a CMP polishing pad conditioned with a CMP pad conditioner made in accordance with embodiment of US Publication No. US2005/0276979, filed Jun. 24, 2005. The figure shows the spiral grooves cut into the surface of the pad.

FIG. 6 is an interferometry map of the surface of a CMP polishing pad after being conditioned with a CMP conditioner made in accordance with embodiments of US Publication No. US2005/0276979, filed Jun. 24, 2005.

FIG. 7 is a graph showing the surface height probability density for the interferometry measurement made in FIG. 6. The value of λ is the x component of the slope of the curve to the right of zero for a y value of 1/e. The value of λ give a measure of the surface roughness for the pad. A small λ value means the pad is smooth and large λ value means the pad is rough.

FIG. 8 is a representation showing the grooved non-planar ceramic substrate coated with CVD diamond according to embodiments of the present invention.

FIG. 9 is a representation showing a raised ring non-planar ceramic substrate coated with CVD diamond according to embodiments of the present invention.

FIGS. 10A and 10B is a representation showing non-linear, substantially concentric broken line non-planar ceramic substrate coated with CVD diamond according to embodiments of the present invention.

FIGS. 11A and 11B is a representation showing non-linear line segments oriented into broken line spirals on the non-planar ceramic substrates coated with CVD diamond according to embodiments of the present invention.

FIG. 12 is a plan view of the non-planar ceramic substrate as shown in 8A.

FIG. 13 is an interferometry map of the surface of a CMP polishing pad after being conditioned with a CMP conditioner made in accordance with embodiments of US Publication No. US2005/0276979, filed Jun. 24, 2005. The conditioner was manufactured with medium sized diamond grit. The surface height maps show the surface for a sample taken from three different radial positions.

FIG. 14 is a graph showing the surface height probability density for the interferometry measurement made in FIG. 13. All three interfermotry measurements are depicted in the graph. The λ values for all three plots were determined and are shown in FIG. 19.

FIG. 15 is an interferometry map of the surface of a CMP polishing pad after being conditioned with a CMP conditioner made in accordance with embodiments of US Publication No. US2005/0276979, filed Jun. 24, 2005. The conditioner was manufactured with fine diamond grit. The surface height maps show the surface for a sample taken from three different radial positions.

FIG. 16 is a graph showing the surface height probability density for the interferometry measurement made in FIG. 15. All three interfermotry measurements are depicted in the graph. The λ values for all three plots were determined and are shown in FIG. 19.

FIG. 17 is an interferometry map of the surface of a CMP polishing pad after being conditioned with a CMP conditioner made in accordance with the present invention. The conditioner was manufactured with a spiral non-planar configuration as depicted in FIG. 12. The surface height maps show the surface for a sample taken from three different radial positions.

FIG. 18 is a graph showing the surface height probability density for the interferometry measurement made in FIG. 17. All three interfermotry measurements are depicted in the graph. The λ values for all three plots were determined and are shown in FIG. 19. FIG. 19 is a graph of the λ values for all three measurements made from the data in FIGS. 14, 16, 18. The graphs shows that the non-planar conditioner from FIG. 12 produced the smoothest pad surface.

FIG. 20 is a graph comparing point cutting CMP conditioners to the edge-shaving CMP conditioners of the present invention in terms of copper removal rate and non-uniformity.

FIG. 21 is a graph comparing point cutting CMP conditioners to the edge-shaving CMP conditioners of the present invention in terms of copper removal rate versus coefficient of friction.

FIG. 22 is a graph comparing point cutting CMP conditioners to the edge-shaving CMP conditioners of the present invention in terms of copper removal rate vs. pad temperature.

FIG. 23 is a graph comparing point cutting CMP conditioners to the edge-shaving CMP conditioners of the present invention in terms of pad cut rates.

### DETAILED DESCRIPTION OF THE INVENTION

As used herein, the term “chemically vapor deposited” or “CVD” refers to materials deposited by vacuum deposition processes, including, but not limited to, thermally activated deposition from reactive gaseous precursor materials, as well as plasma, microwave, DC, or RF plasma arc-jet deposition from gaseous precursor materials. Also as used herein, the term “substantially uniformly distributed” refers both to embodiments of the invention where the diamond particles are evenly distributed over the entire substrate surface, and embodiments where the diamond particles are evenly distributed over selected portions of the substrate surface, as when the diamond particles are applied using a mask or shield. As used herein, the term “carbide-forming material” means a material that is capable, under appropriate conditions, of formation of a covalently bonded compound with carbon in a carbide. Examples include silicon, titanium, molybdenum, tantalum, niobium, vanadium, hafnium, chromium, zirconium, and tungsten, etc. and combinations thereof. As used herein, the term “dispersed” means inclusions or phases distributed in a more abundant matrix phase. Desirably, at least a portion of these inclusions are present at one or more surfaces of the material. The inclusions may be in the form of grains or particles, or may form a network of material that is interspersed with the matrix phase. For example, a material containing a matrix phase of silicon carbide and a second phase of silicon metal dispersed in the matrix could be prepared by impregnating porous silicon carbide with molten silicon and allowing the material to cool below the melting temperature of silicon.

As indicated above, it has been found that substrates comprising silicon carbide, in particular reaction-bonded silicon carbide composites, provide properties that are preferable to those of pure silicon substrates, because of the increased fracture toughness, and the increased stiffness of the silicon carbide. The preferred reaction-bonded silicon carbide material in the composite substrate also has a higher adhesion to chemical vapor deposited diamond as compared to the ceramic material component of the substrate. According to embodiments of the present invention, the use of silicon carbide that has been modified to contain surface regions of silicon metal as a substrate for CVD diamond can be applied to the preparation of any CMP conditioning head. The particular techniques disclosed herein for producing particular roughnesses of diamond coating form additional embodiments of the present invention, whether using particular size distributions of diamond grit, or preferably using a coating without the presence of additional diamond grit. Such novel techniques may be used with the composite silicon carbide substrate disclosed herein, or may be used with any other suitable substrate material, as described herein. Accordingly, the techniques described below may be used with the silicon carbide substrates of the present invention, or may be used with any other substrates, including conventional substrates known in the field. Similarly, the composite silicon carbide substrate of the present invention can be used with the diamond coating techniques described herein, or with other diamond coatings, including conventional diamond coatings known in the field.

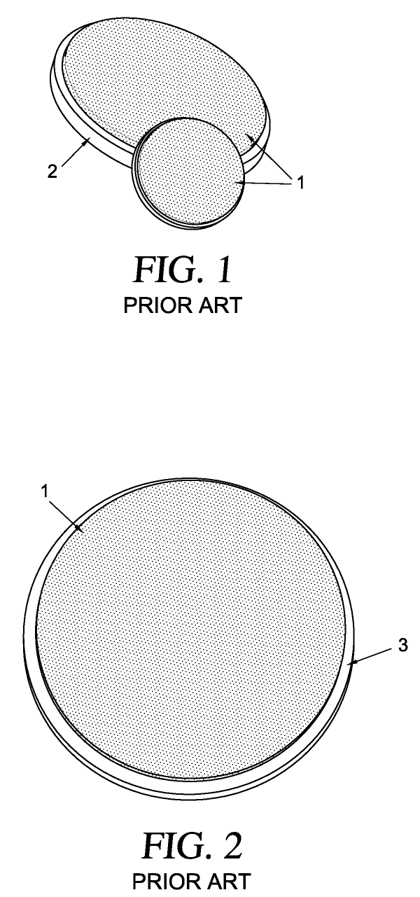

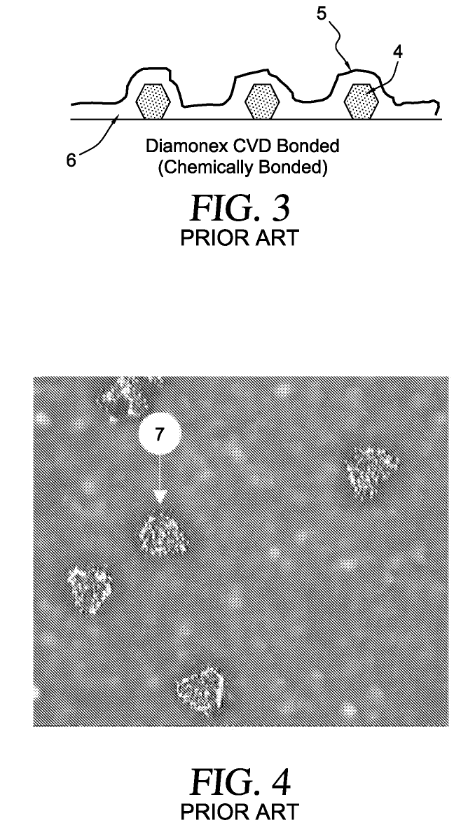

According to embodiments of the present invention, preparation of polishing pad conditioning head FIG. 1 and FIG. 2 is performed according to the following method. In the first step, a layer, preferably a monolayer, of diamond grit 4 having an average particle diameter in the range of from about 1 to about 15 microns is deposited onto a substrate 6 in a highly uniform manner. The density of this diamond grit on the surface of the substrate is from about 100 to about 50,000 grains per mm². If desired, an additional “layer” of smaller diamond grit, typically having an average particle size of less than about 1 micron, can be deposited on the grit-covered substrate. Some of this smaller grit may fall atop the larger grit particles already deposited, while other portions of the smaller grit will fall on areas of the substrate not covered by the larger diamond grit. Preferably, the density of small diamond grit on the surface of the substrate is from about 400 to about 2,000 grains per mm².

After the application of the monolayer of small diamond grit onto the substrate surface in the preparation of a polishing pad conditioner, a uniform layer 5 of CVD diamond is grown onto the exposed surface of substrate 6. The preferred method of CVD diamond deposition grown onto substrates is carried out using a hot filament CVD (HFCVD) reactor of the type described and claimed in Garg, et al., U.S. Pat. No. 5,186,973, issued Feb. 16, 1993, which is incorporated by reference herein as if made a part of the present specification. However, other CVD methods known in the prior art can be used, such as DC plasma, RF plasma, microwave plasma, or RF plasma arc-j et deposition of diamond from gaseous precursor materials. Preferably, the CVD diamond is chemically vapor deposited onto the surface of the substrate such that the CVD diamond layer exhibits enhanced crystal orientation in either the <220>or the <311>direction and the <400>direction as compared to the degree of crystal orientation of industrial grade diamonds. The phrase “chemically vapor deposited” is intended to include the deposition of a layer of CVD diamond resulting from the decomposition of a feed gas mixture of hydrogen and carbon compounds, preferably hydrocarbons, into diamond generating carbon atoms from a gas phase, activated in such a way as to avoid substantially graphitic carbon deposition. The preferred types of hydrocarbons include C₁-C₄ saturated hydrocarbons such as methane, ethane, propane and butane; C₁-C₄ unsaturated hydrocarbons, such as acetylene, ethylene, propylene and butylene, gases containing C and O such as carbon monoxide and carbon dioxide, aromatic compounds such as benzene, toluene, xylene, and the like; and organic compounds containing C, H, and at least one oxygen and/or nitrogen atom, such as methanol, ethanol, propanol, dimethyl ether, diethyl ether, methyl amine, ethyl amine, acetone, and similar compounds. The concentration of carbon compounds in the feed gas mixture can vary from about 0.01% to about 10% by weight, preferably from about 0.2% to about 5% by weight, and more preferably from about 0.5% to about 2% by weight. The resulting diamond film in the HFCVD deposition method is in the form of adherent individual crystallites or a layer-like agglomerate of crystallites substantially free from intercrystalline adhesion binder. The total thickness of the diamond film is from about 1 to about 50 microns, more preferably from about 5 to about 30 microns, and most preferably from about 10 to about 18 microns. The HFCVD process involves activating a feed gas mixture, containing one or more hydrocarbons and hydrogen, by passing the mixture at sub-atmospheric pressure, i.e. no greater than 100 Torr, over a heated filament, made of W, Ta, Mo, Re or a mixture thereof, and flowing the activated gaseous mixture over the heated substrate to deposit the polycrystalline diamond film. The feed gas mixture, containing from 0.1% to about 10% hydrocarbon in hydrogen, becomes thermally activated producing hydrocarbon radicals and atomic hydrogen. The temperature of the filament ranges from about 1800° C. to 2800° C. The substrate is heated to a deposition temperature of about 600° C. to about 1100° C.

The surface roughness resulting from simply growing CVD diamond on a substrate ranges from about 2 to 5 microns from peak-to-valley on a substrate having a thickness of about 10 microns of CVD diamond. In general, the peak-to-valley surface roughness for a typical CVD diamond layer ranges from about ¼ to about ½ the thickness of the CVD diamond that is grown on the substrate. This degree of surface roughness can provide the desired abrasive efficiency for CMP conditioning operations for the CMP pads mentioned above. One difficulty with this concept, is independently controlling the particle size and density of working diamond grains. According to embodiments of the present invention, diamond grit, commercially available from the cutting of natural diamonds and from synthetic industrial grade diamonds, is incorporated into the structure of the thin CVD diamond film. The size of the grit is selected so that the peak-to-valley surface distance is less than or equal to about 15 microns. The diamond grit is uniformly distributed over the surface of the substrate at a density such that only a monolayer of diamond grit particles is established. The average size of the diamond grit preferably is in the range of from about 1 micron to about 15 microns, and more preferably in the range of about 4 microns to about 10 microns. By controlling the size and density of the diamond grit, the abrasive characteristics of the resulting surface can be adjusted and predictably tailored for various improved conditioning applications.

As described above, one method for obtaining a narrow distribution of diamond grains and of controlling the size of those diamond grains is to grow CVD diamond on a substrate that has a surface microstructure having the desired consistency of surface characteristics, and growing the diamond to a level sufficient to obtain the desired grain size and surface roughness. According to embodiments of the present invention, reaction-bonded silicon carbide of the type described above as a substrate composite component is used to assist in obtaining the substrate surface roughness. By carefully controlling the surface microstructure of the silicon carbide to have a consistency corresponding to the desired consistency of diamond grains, and by growing CVD diamond on this substrate microstructure to the desired grain size, a consistent diamond surface, without damage-causing large grains, but with an average grain size and average roughness large enough to provide suitable conditioning results, can be obtained. Another technique for obtaining a similar result is to mechanically score or roughen a smooth surface, such as polished silicon, e.g., by contacting it with highly consistent diameter diamond grit sufficiently to score the surface, removing the grit, and growing CVD diamond on the roughened surface to the desired particle size. Alternatively, grooves and/or ridges can be cut, either mechanically or by laser cutting into the surface of the substrate, and CVD diamond grown thereon to provide the appropriate roughness. Therefore, according to embodiments of the present invention, the final product CMP pad conditioners are manufactured and controlled to produce an exceedingly smooth surface, which, in turn, produces exceedingly smooth part surfaces (e.g. wafer surfaces), by substantially reducing surface defects on the parts being polished.

The non-planar, raised surface patterns are selected preferably in combination with controlling the diamond particle size, to achieve a smooth pad conditioner surface that conditions a pad by “edge-shaving or shaping” as compared to “point-cutting”. The use of the reaction-bonded silicon carbide in the substrate composite contributes to the control of the diamond deposit and growth, in that the increase in adherence of the diamond to the substrate allows from a much thinner, but at least equally robust and durable diamond coating, further reducing processing time and lowering overall production cost. These improvements result in a smoother pad surface, which results in an improved finished product (e.g. wafer, film, etc.).

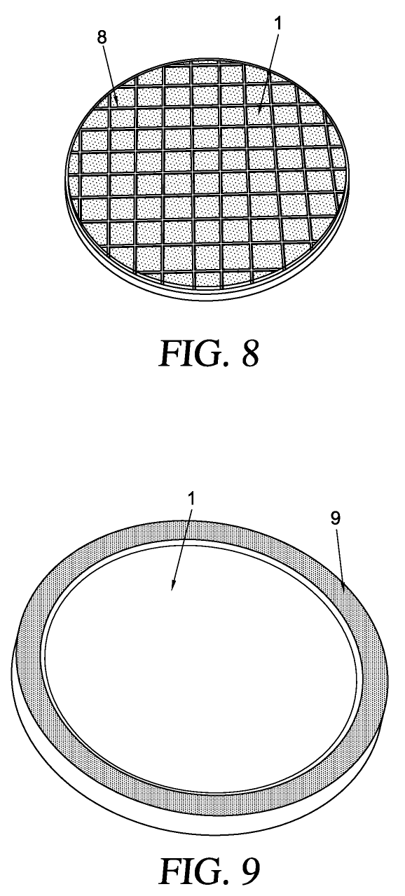

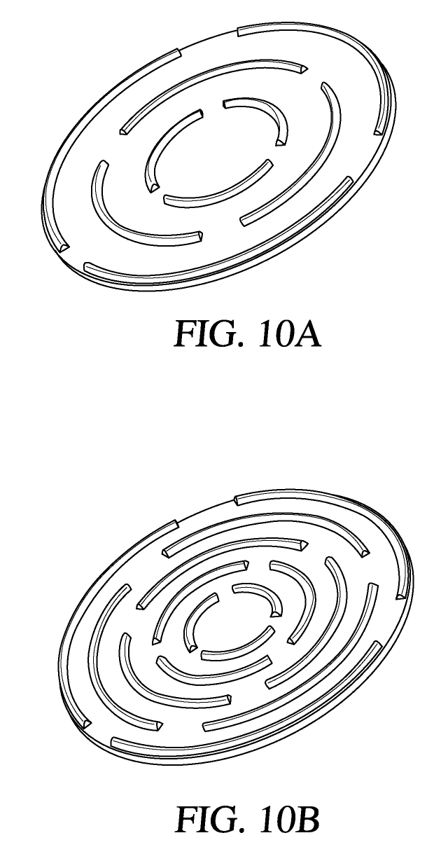

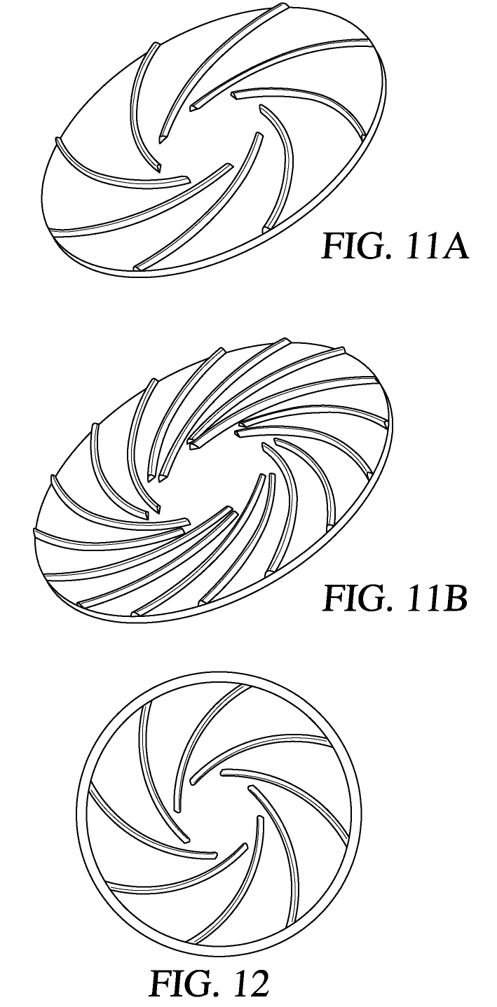

Exemplary conditioning pad surface patterns useful in the present invention include a grid of intersecting lines (FIG. 8), raised outer ring (FIG. 9), a series of concentric circles or ovals (FIGS. 10A & 10B), a spiral pattern beginning at the center of the conditioning head FIGS. 11A & 11B), a series of radial lines extending from a point at or near the center of the conditioning head (not shown), and combinations of these. The grooves 8 may have a depth on the order of about 50 microns to 200 microns, typically about 100 microns to 120 microns, a width of about 0.03 mm to 0.1 mm, typically from about 0.04 mm to 0.05 mm, and a spacing of about 3 mm to 10 mm, typically about 5 mm (spacing will obviously vary considerably for radially extending grooves). An example of a reaction-bonded silicon carbide substrate containing laser-cut grooves suitable for coating with CVD diamond is illustrated in FIG. 8.

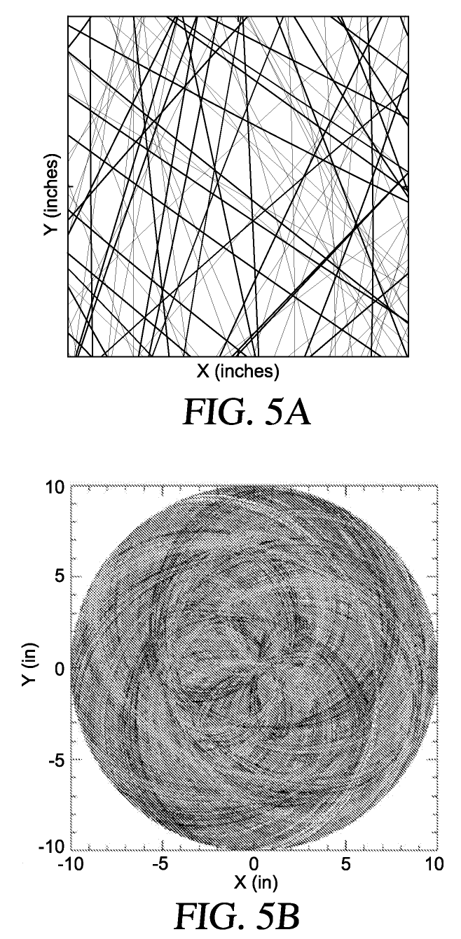

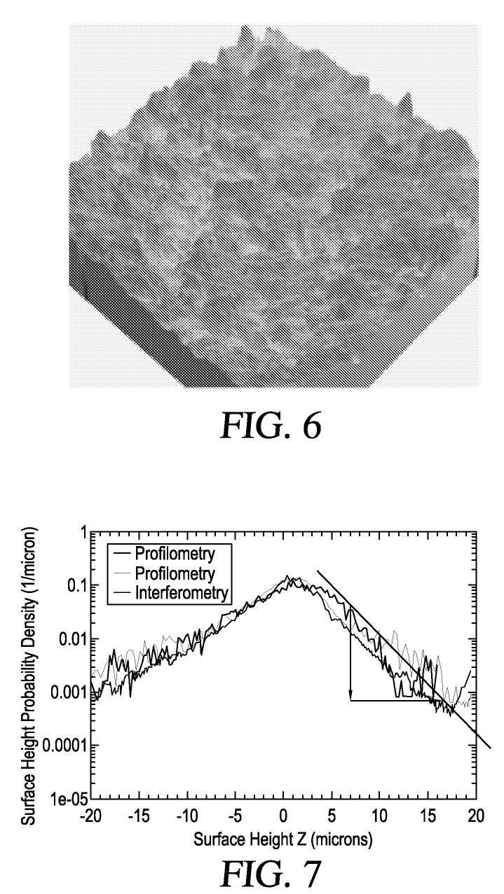

Once again, CMP pad conditioners of the embodiments described in US Publication No. US2005/0276979, filed Jun. 24, 2005, work by each diamond crystal impacting or cutting the CMP pad surface. Therefore, each diamond acts like a single point cutting tool. These diamond crystals then impact or scratch and/or cut the surface of the pad in rotating pattern based on the rotation of the pad and the rotation for the conditioner as shown in FIGS. 5A and 5B. This creates texture differences in the pad base (surface) across the radial distance of the pad base. FIG. 6 is an interferometry measurement of a typical pad surface that was conditioned using a CMP pad conditioner fabricated with diamond grit. FIG. 7 is a graph of the surface height probability for the pad surface in FIG. 6. The slope of the curve past to the right of the zero surface height gives information as to the texture of the pad surface. If the slope is shallow then the pad surface has large asperities and is rougher than a slope that is steep. A method to quantify the slope is to measure a value lambda (λ). Lambda (λ) is the x component of the slope where the y component is defined as 1/e. Therefore if lambda is small then the surface is smooth.

CMP pad conditioners, according to embodiments of the present invention are based on creating shaping edges instead of cutting points. The shaping edges are created by the non-planar, raised substrate surface features. For example, the embodiment shown in FIG. 11A has a series of spiral raised surfaces 11. These raised surfaces are comprised of a top surface parallel to the substrate surface and an intersection angular surface. The intersection of the parallel surface and the angular surface creates a pre-selected edge. This edge is the active region of the conditioner that then impacts or shapes the CMP pad surface. This results in the conditioner “shaving” the surface of the pad rather than “scratching” and cutting the pad. As a result, according to embodiments of the present invention, substantially uniform texturing of the pad surface occurs from center to edge of the pad surface. For example, according to one preferred embodiment, a conditioner of this type is constructed with a substrate that has a non-planar surface. The non-planarity of the pad conditioning surface can be a series of raised surfaces oriented as continuous or broken line spiral ribs or concentric circles, or any engineered surface as desired that will give the desired results; for example, those as shown in FIGS. 10A and 10B and FIGS. 11A and 11B. A surface is prepared and then coated with CVD diamond to the desired thickness that gives the desired diamond roughness. Again, the preferred use, in the composite substrate, of a reaction-bonded silicon carbide having a higher adhesion to chemical vapor deposited diamond than the selected ceramic composite component allows for the deposition of a thinner CVD diamond layer that also contributes to a more substantially uniform diamond layer roughness.

### EXAMPLES

The examples and comparative examples and the discussion that follow further illustrate the ability to prepare CVD diamond coatings on a composite substrate of a ceramic material and a carbide-forming composite substrate material for a variety of applications, including but not limited to: conditioning of conventional hard polyurethane CMP pads, fibrous CMP pads and fixed abrasive CMP pads, etc. The comparative examples and examples are for illustrative purposes and are not meant to limit the scope of the claims in any way.

### Example 1

A two (2) inch diameter by 0.135 inch thick round substrate of PUREBIDE R2000 reaction-bonded SiC substrate material (Morgan AM&T, St. Marys, Pa.) with a lapped surface finish was seeded with a 1 to 2 micron diamond by mechanically rubbing the surface. The excess diamond was then removed from the surface. The substrate was then placed in a CVD diamond deposition reactor. The reactor was closed and 15.95 kW (145 volts and 110 amps) were provided to heat the filament to about 2000° C. A mixture of 72 sccm (standard cubic centimeters per minute) of methane in 3.0 slpm (standard liters per minute) of hydrogen was fed into the reactor for a period of 1.5 hours at a pressure of 30 Torr to deposit about 1 to 2 microns of polycrystalline diamond onto the exposed surface of the diamond grit and the reaction-bonded SiC substrate. The power was increased to 21.24 kW (177 volts and 120 amps) at a pressure of 25 Torr for an additional 29.5 hours. The filament power was turned off and the coated substrate was cooled to room temperature under flowing hydrogen gas. A total of 10 microns of coherent polycrystalline diamond was deposited onto the previously deposited CVD diamond layer. The sample was then examined and found to have a uniform adherent diamond coating. The sample was then hand rubbed on a polyurethane CMP polishing pad and reexamined under 20× magnification. The diamond surface was intact. The conditioning head was then used on an Applied Materials Mirra CMP System to successfully condition a fixed abrasive CMP pad.

### Example 2

Two inch diameter by 0.135 inch thick round CMP pad conditioning disks for fixed abrasive CMP pads were fabricated from three PUREBIDE R2000 reaction-bonded SiC substrates, each having its surface finished by a different technique. The first substrate was finished by through-feed grinding, the second substrate was finished by Blanchard grinding, and the third substrate was finished by lapping. The surface roughness of each substrate was measured using a KLA Tencor P11 profilometer before and after the surface finishing procedure. The second sample was less rough than the first, and the third sample was less rough than the second. Each of the substrates was then coated with CVD diamond to the same thickness in the same reactor at the same time under the same conditions. Surface roughness was then measured using the same KLA Tencor profilometer and compared to the original roughness and to each other. In each case, the substrate with the higher original roughness also contained the higher after-coating roughness.

### Example 3

Two inch by 0.135 inch thick round PURBIDE R2000 reaction-bonded SiC substrates was prepared by laser cutting grooves into the surface of the substrate as shown in FIG. 8. The surface was seeded with 1 to 2 micron diamond by mechanically rubbing the surface. The excess diamond was then removed from the surface. The substrate was then coated with CVD diamond as described in Example 1. The sample was then hand rubbed on a polyurethane CMP polishing pad and reexamined. The majority of the cutting action occurred at the edges of the grooves.

### Example 4

Two inch by 0.135 inch thick round PUREBIDE R2000 reaction-bonded SiC substrates having a 3 mm wide raised ring around the outer diameter, as shown in FIG. 9, was seeded with 1 to 2 micron diamond by mechanically rubbing the surface. The excess diamond was then removed from the surface. The substrate was then coated with CVD diamond as described in Example 1. The sample was then hand rubbed on a polyurethane CMP polishing pad and reexamined. The majority of the cutting action occurred at the edges of the raised ring. Samples were then used effectively to condition fixed abrasive pads (FAP) on an AMAT Mirra tool.

### Example 5

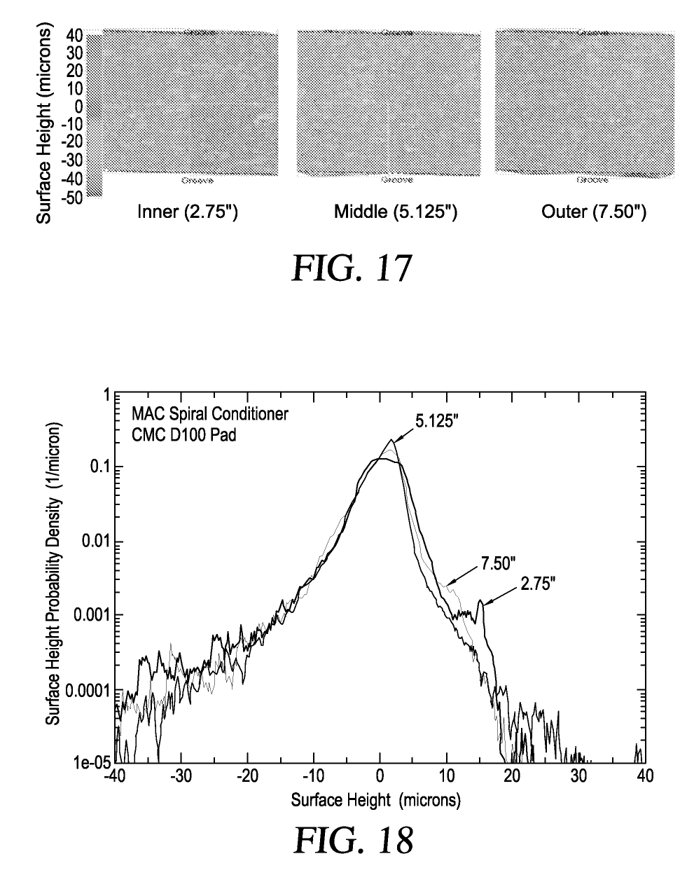

Four inch by 0.100 inch thick round PUREBIDE R2000 reaction-bonded SiC substrates having eight spiral raised ribs as shown in FIGS. 11A and 11B was seeded with 1 to 2 micron diamond by mechanically rubbing the surface. The excess diamond was then removed from the surface. The substrate was then coated with CVD diamond as described in Example 1. The sample was then hand rubbed on a polyurethane CMP polishing pad and reexamined. The majority of the cutting action occurred at the edges of the raised spiral vanes. The sample was then used to condition a polyurethane pad on an AMAT Mirra tool. The pad surface showed uniform surface texture, as shown in FIG. 17.

### Example 6

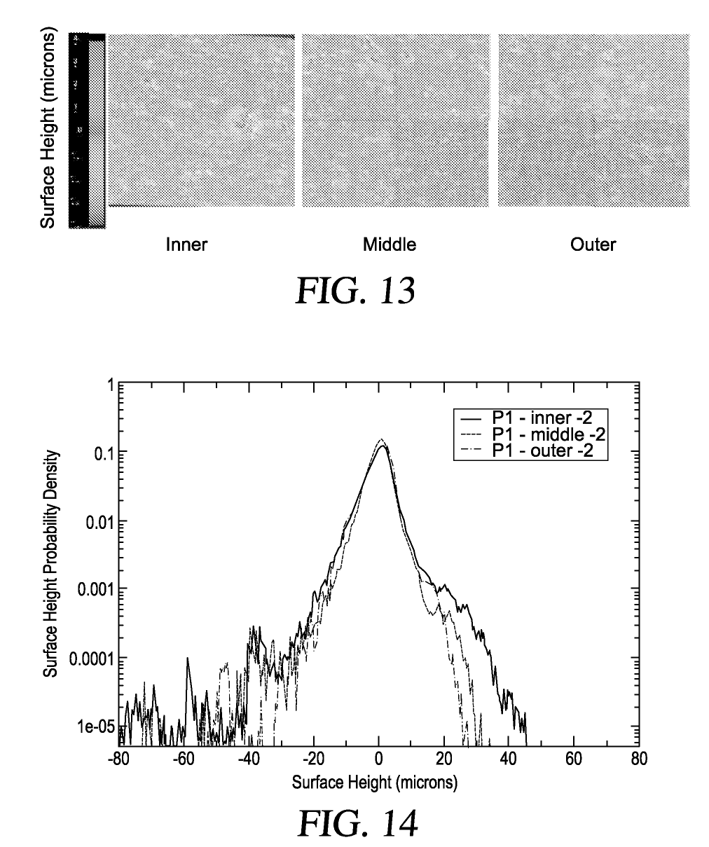

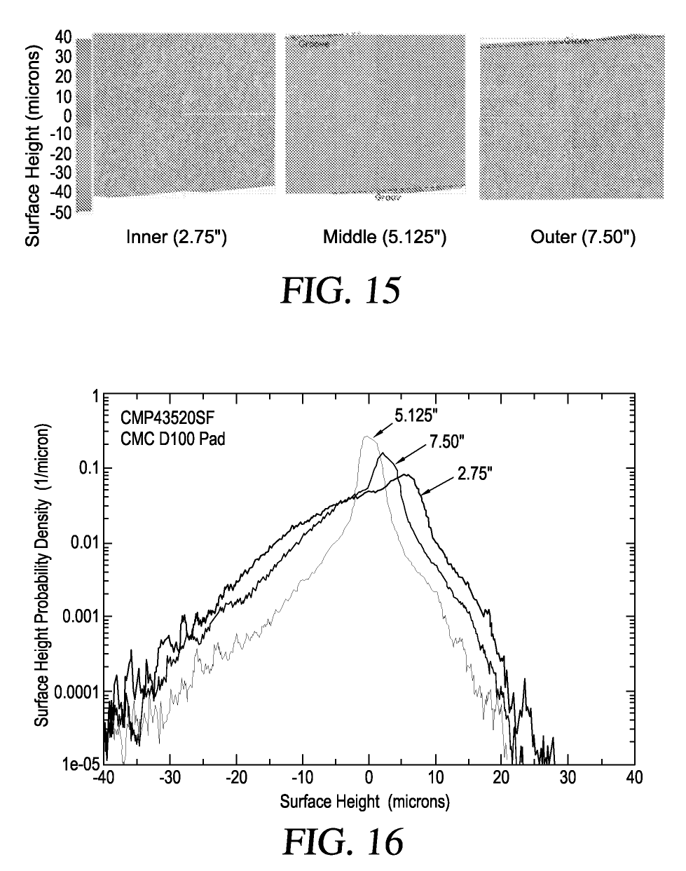

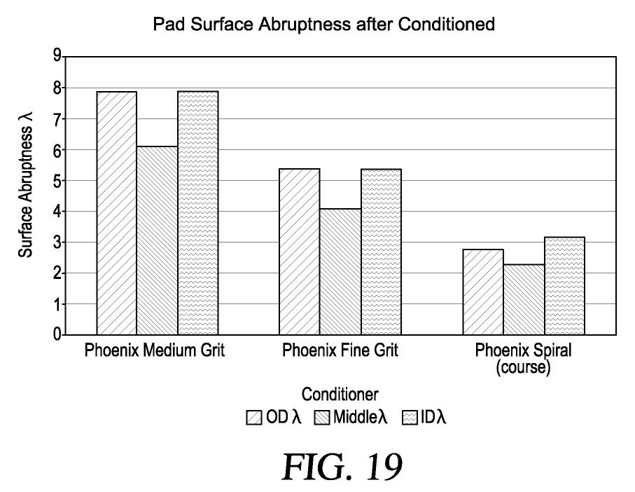

To compare the effect of a conditioner on the surface texture of a CMP pad, three CMP conditioners were fabricated and used to condition three CMP pads. The surface textures of the three CMP pads were then analyzed by using interferometry. The first CMP conditioner was fabricated using 50 micron diamond grit in an embodiment of US Publication No. US2005/0276979, filed Jun. 24, 2005. FIG. 13 shows the interferometry for measurements made in the center, middle, and outer edge of the CMP pad. FIG. 14 shows a graph of the surface height probability based on the interferometry measurements. The second CMP conditioner was fabricated using 35 micron diamond grit in an embodiment of US Publication No. US2005/0276979, filed Jun. 24, 2005. FIG. 15 shows the interferometry for measurements made in the center, middle, and outer edge of the CMP pad. FIG. 16 shows a graph of the surface height probability based on the interferometry measurements. The third conditioner was fabricated as described in Example 5. FIG. 17 shows the interferometry for measurements made in the center, middle, and outer edge of the CMP pad. FIG. 18 shows a graph of the surface height probability based on the interferometry measurements. The values of lambda were determined for all three conditioner and all three locations. FIG. 19 is a plot of the values for lambda for all three conditioners. FIG. 19 shows that the all three conditioner has texture differences between the three regions on the pad. However, the third conditioner made by the present invention had the smoothest pad surface and the least variation across the pad surface.

### Example 7

Blanket copper wafers of a dimension of 200 mm were used. The selected conditioning pad used were IC 1020M groove (Rohm & Haas, Newark, Del.). A slurry was used comprising 200 ml of Fujima PL-7103 slurry with 800 ml of distilled water with 33 g of ultra pure hydrogen peroxide. A distilled water rinse was applied at a flow rate of 2000 ml/min. for 30 seconds. The following Diomonex® discs (Morgan Advanced Ceramics, Allentown, Pa.) were used: finest grit (CMP43520SF); medium grit (CMP45020SF); Coarse grit (CMP47520SF) and No-grit (CMP4S840—2-runs). In-situ pad conditioning was applied at a downforce of about 6 lb. The conditioning was run as a tweaked optimized sweep or sinusoidal sweep (for the second no-grit run). Wafer polishing was effected at a polishing pressure of 2 psi, with a platen sliding velocity of 42 RPM for 60 seconds.

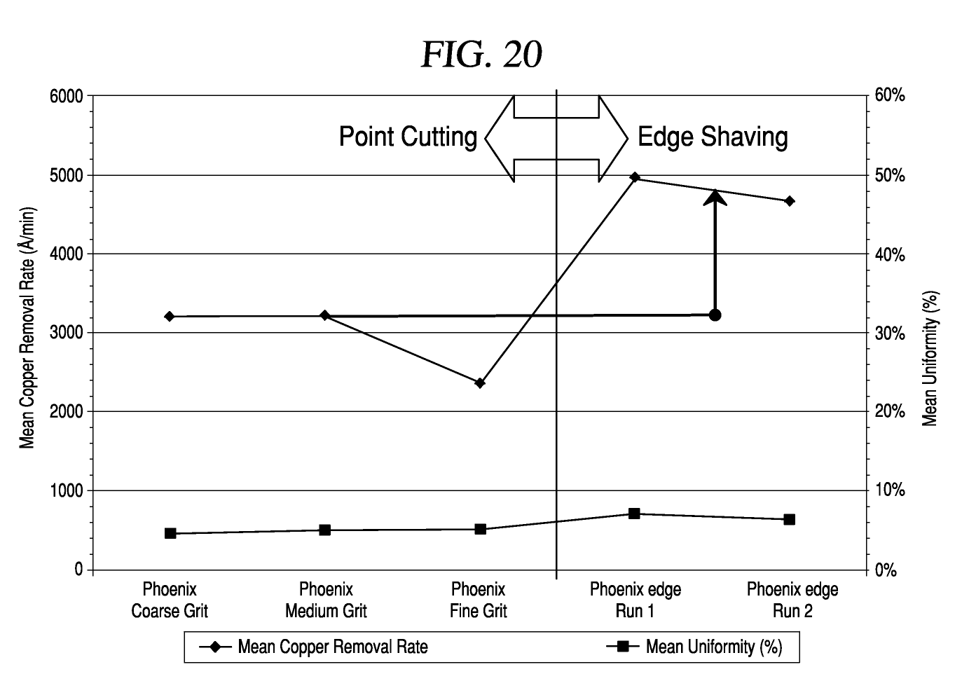

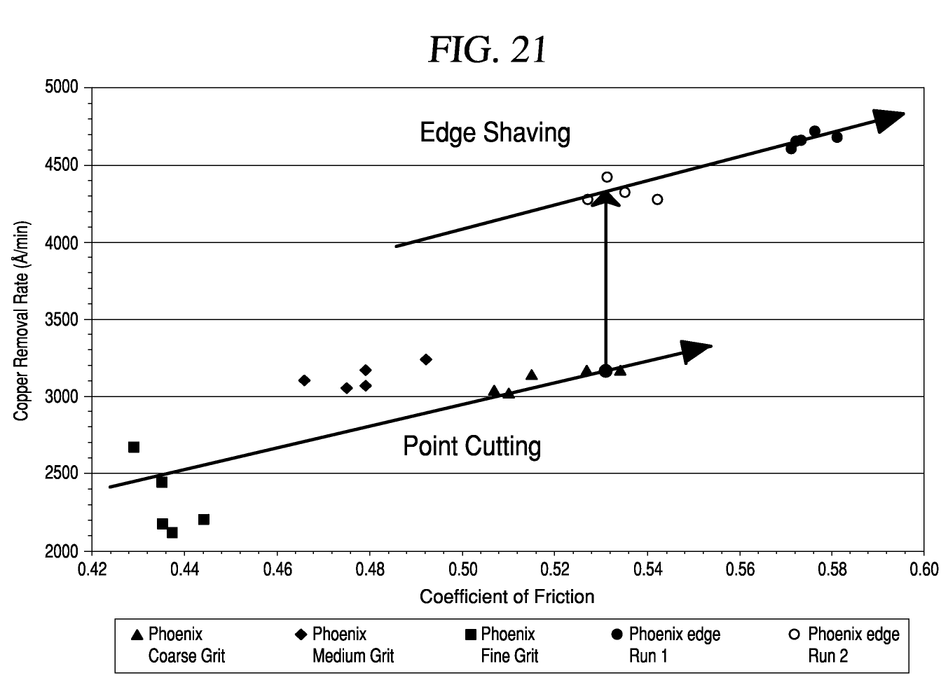

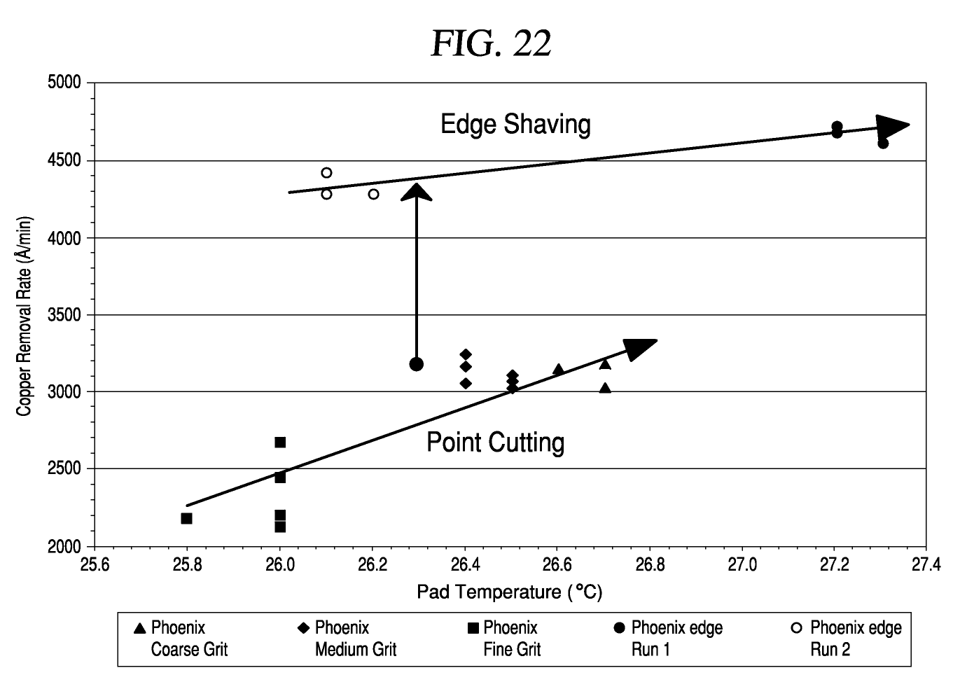

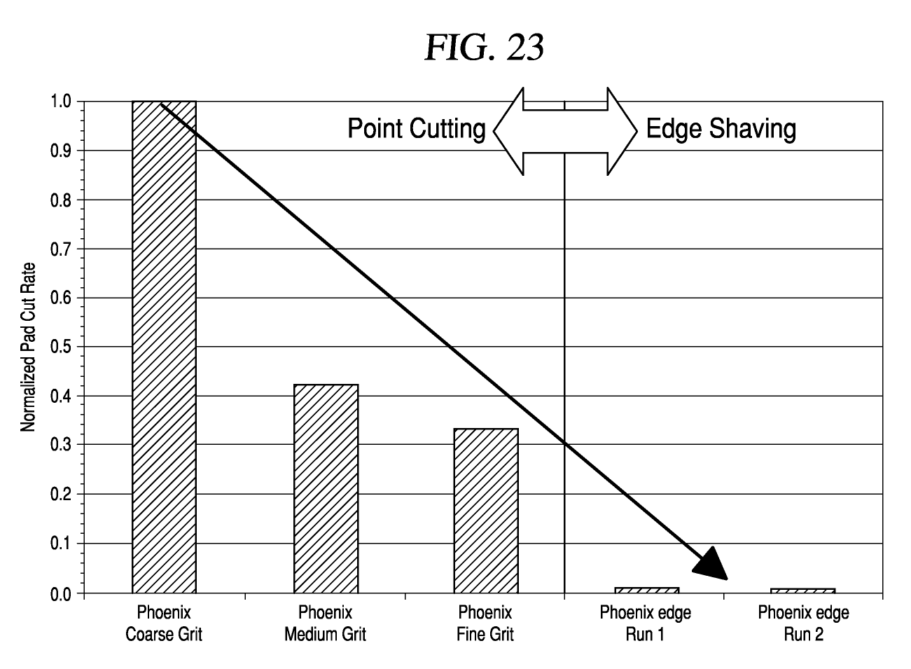

FIGS. 20-22 are graphs of plotted data points collected relative to investigations comparing copper removal rates of known point-cufting CMP conditioning heads with the edge-shaving CMP conditioning heads of the present invention. More specifically, FIG. 20 shows the comparative copper removal rate using both point-cutting and edge-shaving CMP conditioning heads. The plotted results show a nearly 50% increase in copper removal rate using the edge-shaving embodiments of the present invention. FIG. 21 shows the comparative copper removal rate versus coefficient of friction using both point-cutting and edge-shaving CMP conditioning heads. The plotted results show approximately a 42% increase in copper removal rate using the edge-shaving embodiments of the present invention. FIG. 22 shows the comparative copper removal versus pad temperature using both point-cutting and edge-shaving CMP conditioning heads. The plotted results show approximately a 50% increase in copper removal rate at the same temperature using the edge-shaving embodiments of the present invention.

Additionally, experiments were conducted to determine pad cut rates when using both point-cutting and edge-shaving CMP conditioning heads. The plotted results show a dramatic decrease in pad wear and material removal when using the CMP conditioning heads of the present invention as compared to the wear sustained using varying grit sizes with known point-cutting CMP conditioning heads.

While the present invention has been described in detail with reference to specific embodiments thereof, it will be apparent to one skilled in the field that various changes, modifications, and substitutions can be made, and equivalents employed without departing from, and are intended to be included within, the scope of the claims.

What is claimed is:

1. A conditioning head comprising a CVD diamond-coated composite, said conditioning head further comprising:
(a) an uncoated substrate comprising a substrate surface, said substrate further comprising:
(1) a first phase comprising at least one ceramic material; and
(2) a second phase comprising at least one carbide-forming material; and
wherein said substrate surface comprises at least one area of raised non-planar edge-shaving region relative to the substrate surface.

2. A conditioning head comprising a CVD diamond-coated composite, said conditioning head further comprising:
(a) an uncoated substrate comprising a substrate surface, said substrate further comprising:
(1) a first phase comprising at least one ceramic material; and
(2) a second phase comprising at least one carbide-forming material; and
(b) a chemical vapor deposited diamond coating disposed on at least a portion of the substrate surface, to create a coated substrate; and
wherein said substrate surface comprises at least one area of raised non-planar edge-shaving region relative to the substrate surface.

3. A conditioning head comprising a CVD diamond-coated composite, said conditioning head further comprising:
(a) an uncoated substrate comprising a substrate surface, said substrate further comprising:
(1) a first phase comprising at least one ceramic material; and
(2) a second phase comprising at least one carbide-forming material;
wherein said uncoated substrate has a measurable degree of bowing; and
(b) a chemical vapor deposited diamond coating disposed on at least a portion of the substrate surface, to create a coated substrate, said coated substrate having a measurable degree of bowing that is substantially similar to the degree of bowing of the uncoated substrate; and
wherein said substrate surface comprises at least one area of raised non-planar edge-shaving region relative to the substrate surface.

4. The composite of claim 1, wherein the raised non-planar edge-shaving region is selected from the group consisting of concentric circles, broken concentric circles, spirals, broken spirals, linear, broken linear, curved segments, broken curved segments, and combinations thereof.

5. The conditioning head of claim 1, wherein at least one of the second phase materials is dispersed in a matrix formed by the first phase material.

6. The conditioning head of claim 1, wherein at least one of the first phase materials is dispersed in a matrix formed by the second phase material.

7. The conditioning head of claim 1, wherein the region of carbide-forming material comprises a coating on one or more pores formed in the region of ceramic material.

8. The conditioning head of claim 1, wherein the first phase comprises one or more grains of the ceramic material dispersed within a matrix of the second phase, comprising the carbide-forming material.

9. The conditioning head of claim 1, wherein the ceramic material comprises silicon carbide, silicon nitride, silicon aluminum oxynitride, aluminum nitride, tungsten carbide, tantalum carbide, titanium carbide, boron nitride, and combinations thereof.

10. The conditioning head of claim 9, wherein the region of silicon carbide comprises fully sintered alpha silicon carbide.

11. The conditioning head of claim 1, wherein the carbide forming material is a reaction-bonded silicon carbide-containing material.

12. The conditioning head of claim 9, wherein the carbide-forming material comprises silicon, titanium molybdenum, tantalum, niobium, vanadium, hafnium, chromium, zirconium, and tungsten, and combinations thereof.

13. The conditioning head of claim 1, further comprising:
a first layer of diamond grit having an average grain size in the range of about 1 micron to about 25 microns and substantially uniformly distributed with respect to an exposed surface of the substrate; and
wherein the layer of chemical vapor deposited diamond disposed on the diamond grit-covered substrate,
whereby the layer of chemical vapor deposited diamond at least partially encases and bonds the diamond grit to the substrate.

14. The conditioning head of claim 13 wherein the average grain size of the diamond grit is in the range of about 2 microns to about 10 microns.

15. The conditioning head of claim 13 wherein said grit is substantially uniformly distributed with respect to the surface of said substrate at a density between about 100 to about 50000 grains per mm².

16. The conditioning head of claim 13 wherein said grit is substantially uniformly distributed on the surface of said substrate at a density of about 400 to about 2000 grains per mm².

17. The conditioning head of claim 13, further comprising a layer of diamond grit having an average diameter less than 1 micron and that is substantially uniformly distributed with respect to said first layer and with respect to remaining exposed surface of the substrate and beneath said layer of chemical vapor deposited diamond.

18. The conditioning head of claim 13, further comprising a backing layer bonded to said conditioning head.

19. The conditioning head of claim 13 wherein said diamond grit has been distributed over the exposed surface of said substrate by an air dispersion process, comprising dropping the grit at a controlled rate from a fixed height above said exposed surface into a moving air current thereby dispersing the diamond grit in a lateral direction across said exposed surface while moving said source in a direction substantially orthogonal to the direction of the air current.

20. The conditioning head of claim 13, wherein the ceramic material comprises silicon carbide and the carbide-forming material comprises silicon.

21. The conditioning head of claim 13, wherein diamond layer is bonded directly to the substrate, without encased or bonded particles of grit.

22. A polishing pad conditioning head, comprising:
(a) a substrate having a surface, and comprising:
(1) a first phase comprising at least one ceramic material; and
(2) a second phase comprising at least one carbide-forming material, and having a first side and a second side;
(b) a layer of diamond grit having an average grain size in the range of about 1 micron to about 150 microns substantially uniformly distributed with respect to said first and second sides; and
(c) a layer of chemical vapor deposited diamond deposited on the grit-covered first and second sides, whereby the layer of chemical vapor deposited diamond encases and bonds said diamond grit to said sides; and
wherein said substrate surface comprises at least one area of raised non-planar edge-shaving region relative to the substrate surface.

23. A method of conditioning a CMP pad, comprising the use of a conditioning head comprising a CVD diamond-coated composite having a diamond coated surface comprising at least one area of raised non-planar orientation relative to the diamond coated surface, the at least one area of raised non-planar orientation being disposed to provide at least one cutting edge, whereby the CMP pad is conditioned by the at least one cutting edge shaving the surface of the CMP pad.

24. A method of making a semiconductor comprising the steps of:
contacting a CMP conditioning pad to a surface of the semiconductor, said conditioning pad treated by the conditioning head of claim 1.

25. A method of making a semiconductor comprising the steps of:
contacting a CMP conditioning pad to a surface of the semiconductor, said conditioning pad treated by the conditioning head of claim 2.

26. A method of making a semiconductor comprising the steps of:
contacting a CMP conditioning pad to a surface of the semiconductor, said conditioning pad treated by the conditioning head of claim 3.

27. A method of making a semiconductor comprising the steps of:
contacting a CMP conditioning pad to a surface of the semiconductor, said conditioning pad treated by the conditioning head of claim 22

28. A semiconductor having a surface treated by a CMP conditioning pad, said conditioning pad treated by the CMP conditioning pad of claim 1.

29. A semiconductor having a surface treated by a CMP conditioning pad, said conditioning pad treated by the CMP conditioning pad of claim 2.

30. A semiconductor having a surface treated by a CMP conditioning pad, said conditioning pad treated by the CMP conditioning pad of claim 3.

31. A semiconductor having a surface treated by a CMP conditioning pad, said conditioning pad treated by the CMP conditioning pad of claim 22.
